(19) United States
(12) Patent Application Publication
(10) Pub. No.: US 2025/0210241 A1
(43) Pub. Date: Jun. 26, 2025

(54) Spin Orbit Torque (SOT) Device Having a Topological Insulator Layer and a Diffusion Barrier Layer

(71) Applicant: Western Digital Technologies, Inc., San Jose, CA (US)

(72) Inventors: Susumu OKAMURA, San Jose, CA (US); Brian R. YORK, San Jose, CA (US); James Mac FREITAG, Sunnyvale, CA (US)

(73) Assignee: Western Digital Technologies, Inc., San Jose, CA (US)

(21) Appl. No.: 18/392,230

(22) Filed: Dec. 21, 2023

(51) Int. Cl. H01F 10/32; G11B 5/39; H10N 50/20; H10N 50/85

(52) U.S. Cl. CPC H01F 10/329; G11B 5/3909; H01F 10/3254; H10N 50/20; H10N 50/85

(57) ABSTRACT

The present disclosure generally relates to topological insulator (TI) based spin-orbit torque (SOT) devices. The SOT device comprises an amorphous seed layer, a textured seed layer having a (001) orientation disposed on the amorphous seed layer, an insulating layer disposed over the textured seed layer, a diffusion barrier layer having a (001) orientation disposed on the insulating layer, a BiSb layer having a (012) orientation disposed on the diffusion barrier layer, an interlayer having a (001) orientation disposed on the BiSb layer, and a ferromagnetic layer having a (001) orientation disposed on the interlayer. The diffusion barrier layer and the interlayer each individually comprises one or more of NiAl and RuAl, and prevent Sb migration from the BiSb layer while transmitting the (001) orientation to the ferromagnetic layer.

### BACKGROUND OF THE DISCLOSURE

### Field of the Disclosure

Embodiments of the present disclosure generally relate to topological insulator (TI) based spin-orbit torque devices.

### Description of the Related Art

BiSb layers are narrow band gap topological insulators with both giant spin Hall effect and high electrical conductivity. BiSb is a material that has been proposed in various spin-orbit torque (SOT) device applications, such as for a spin Hall layer for spintronic logic devices, magnetoresistive random access memory (MRAM) devices, sensors, magnetic recording read heads, and energy-assisted magnetic recording (EAMR) write heads.

However, utilizing BiSb materials in commercial SOT applications can present several obstacles. For example, BiSb materials have low melting points, large grain sizes, significant Sb migration issues upon thermal annealing due to its film roughness, difficulty maintaining a desired (012) or (001) orientation for maximum spin Hall effect, and are generally soft and easily damaged by ion milling. Furthermore, the requirements of the properties of the BiSb layer vary depending on the type of SOT device. For example, devices where current flows current-in-plane (CIP) have different property requirements than devices where current flows current-perpendicular-plane (CPP).

Therefore, there is a need for improved BiSb layers having various desired properties tailored to specific SOT devices.

### SUMMARY OF THE DISCLOSURE

The present disclosure generally relates to topological insulator (TI) based spin-orbit torque (SOT) devices. The SOT device comprises an amorphous seed layer, a textured seed layer having a (001) orientation disposed on the amorphous seed layer, an insulating layer disposed over the textured seed layer, a diffusion barrier layer having a (001) orientation disposed on the insulating layer, a BiSb layer having a (012) orientation disposed on the diffusion barrier layer, an interlayer having a (001) orientation disposed on the BiSb layer, and a ferromagnetic layer having a (001) orientation disposed on the interlayer. The diffusion barrier layer and the interlayer each individually comprises one or more of NiAl and RuAl, and prevent Sb migration from the BiSb layer while transmitting the (001) orientation to the ferromagnetic layer.

In one embodiment, a spin orbit torque (SOT) device comprises a textured seed layer having a (001) orientation, an insulating layer disposed on the textured seed layer, a diffusion barrier layer having a (001) orientation disposed on the insulating layer, the diffusion barrier layer comprising one or more of NiAl and RuAl, a BiSb layer disposed on the diffusion barrier layer, the BiSb layer having a (012) orientation, an interlayer having a (001) orientation disposed on the BiSb layer, the interlayer comprising one or more of NiAl and RuAl, and a ferromagnetic (FM) layer disposed on the interlayer, the FM layer having a (001) orientation.

In another embodiment, a spin orbit torque (SOT) device comprises an amorphous seed layer, a textured seed layer having a (001) orientation disposed on the amorphous seed layer, an insulating layer disposed over the textured seed layer, a first diffusion barrier layer having a body-centered cubic (BCC) (001) orientation disposed on the insulating layer, the first diffusion barrier layer comprising one or more of NiAl and RuAl, a BiSb layer disposed on the first diffusion barrier layer, the BiSb layer having a (012) orientation, an interlayer having a BCC (001) orientation disposed on the BiSb layer, the interlayer comprising one or more of NiAl and RuAl, and a ferromagnetic (FM) layer disposed on the interlayer, the FM layer having a (001) orientation.

In yet another embodiment, a spin orbit torque (SOT) device comprises an amorphous seed layer, a textured seed layer having a (001) orientation disposed in contact with the amorphous seed layer, the textured seed layer comprising one or more of NiAl and RuAl; an insulating layer disposed in contact with the textured seed layer, a diffusion barrier layer having a body-centered cubic (BCC) (001) orientation disposed in contact with the insulating layer, the diffusion barrier layer comprising NiAl, a BiSb layer disposed in contact with the diffusion barrier layer, the BiSb layer having a (012) orientation, an interlayer having a BCC (001) orientation disposed in contact with the BiSb layer, the interlayer comprising NiAl, and a ferromagnetic (FM) layer disposed in contact with the interlayer, the FM layer comprising NiFe or CoFe and having a (001) orientation.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of certain embodiments of a magnetic media drive including a write head having a SOT MTJ device.

FIG. 2 is a fragmented, cross-sectional side view of certain embodiments of a read/write head having a SOT MTJ device.

FIGS. 3A-3C illustrate SOT devices, according to various embodiments.

FIG. 4A illustrates a current-in-plane (CIP) SOT device, according to one embodiment.

FIG. 4B illustrates a current-perpendicular-plane (CPP) SOT device, according to another embodiment.

FIG. 5A is a schematic cross-sectional view of a SOT device for use in a MAMR write head, such as the MAMR write head of the drive of FIG. 1 or other suitable magnetic media drives.

FIGS. 5B-5C are schematic MFS views of certain embodiments of a portion of a MAMR write head with a SOT device of FIG. 5A.

FIG. 6 is a schematic cross-sectional view of a SOT MTJ used as a MRAM device.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to topological insulator (TI) based spin-orbit torque (SOT) devices. The SOT device comprises an amorphous seed layer, a textured seed layer having a (001) orientation disposed on the amorphous seed layer, an insulating layer disposed over the textured seed layer, a diffusion barrier layer having a (001) orientation disposed on the insulating layer, a BiSb layer having a (012) orientation disposed on the diffusion barrier layer, an interlayer having a (001) orientation disposed on the BiSb layer, and a ferromagnetic layer having a (001) orientation disposed on the interlayer. The diffusion barrier layer and the interlayer each individually comprises one or more of NiAl and RuAl, and prevent Sb migration from the BiSb layer while transmitting the (001) orientation to the ferromagnetic layer.

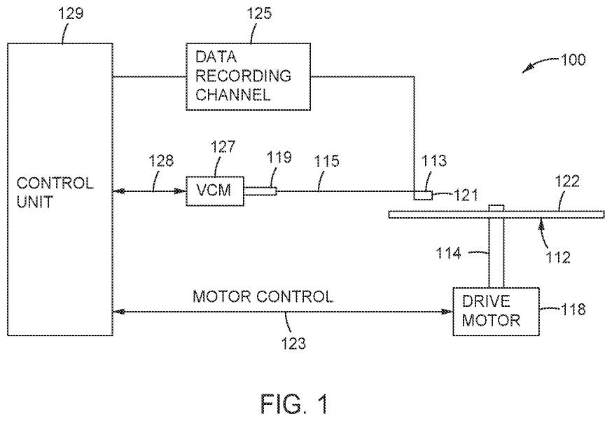

FIG. 1 is a schematic illustration of certain embodiments of a magnetic media drive 100 including a magnetic recording head having a SOT magnetic tunnel junction (MTJ) device. Such a magnetic media drive may be a single drive or comprise multiple drives. For the sake of illustration, a single disk drive 100 is shown according to certain embodiments. As shown, at least one rotatable magnetic disk 112 is supported on a spindle 114 and rotated by a drive motor 118. The magnetic recording on each magnetic disk 112 is in the form of any suitable patterns of data tracks, such as annular patterns of concentric data tracks (not shown) on the magnetic disk 112.

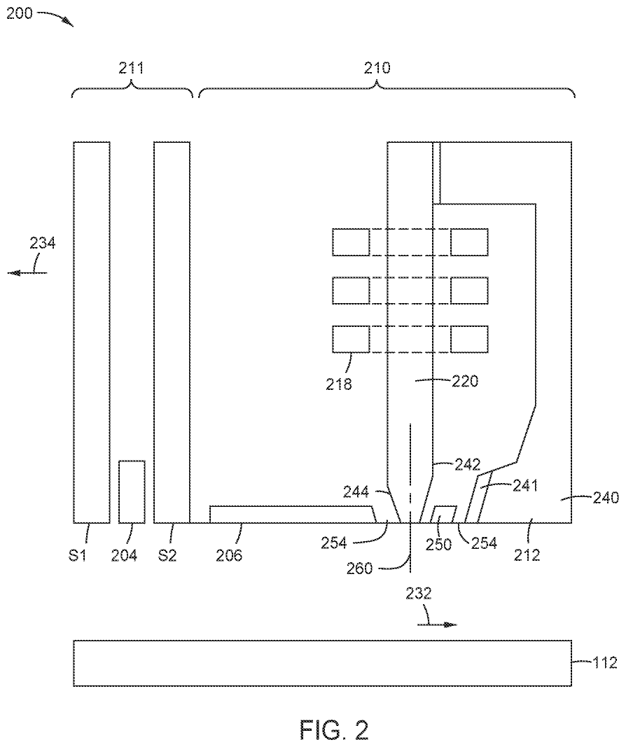

At least one slider 113 is positioned near the magnetic disk 112, each slider 113 supporting one or more magnetic head assemblies 121 that include a SOT device. As the magnetic disk 112 rotates, the slider 113 moves radially in and out over the disk surface 122 so that the magnetic head assembly 121 may access different tracks of the magnetic disk 112 where desired data are written. Each slider 113 is attached to an actuator arm 119 by way of a suspension 115. The suspension 115 provides a slight spring force which biases the slider 113 toward the disk surface 122. Each actuator arm 119 is attached to an actuator means 127. The actuator means 127 as shown in FIG. 2 may be a voice coil motor (VCM). The VCM includes a coil movable within a fixed magnetic field, the direction and speed of the coil movements being controlled by the motor current signals supplied by control unit 129.

During operation of the disk drive 100, the rotation of the magnetic disk 112 generates an air bearing between the slider 113 and the disk surface 122 which exerts an upward force or lift on the slider 113. The air bearing thus counter-balances the slight spring force of suspension 115 and supports slider 113 off and slightly above the disk surface 122 by a small, substantially constant spacing during normal operation.

The various components of the disk drive 100 are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads on the assembly 121 by way of recording channel 125.

The above description of a typical magnetic media drive and the accompanying illustration of FIG. 1 are for representation purposes only. It should be apparent that magnetic media drives may contain a large number of media, or disks, and actuators, and each actuator may support a number of sliders.

FIG. 2 is a fragmented, cross-sectional side view of certain embodiments of a read/write head 200 having a SOT device. The read/write head 200 faces a magnetic media 112. The read/write head 200 may correspond to the magnetic head assembly 121 described in FIG. 1. The read/write head 200 includes a media facing surface (MFS) 212, such as a gas bearing surface, facing the disk 112, a write head 210, and a magnetic read head 211. As shown in FIG. 2, the magnetic media 112 moves past the write head 210 in the direction indicated by the arrow 232 and the read/write head 200 moves in the direction indicated by the arrow 234.

In some embodiments, the magnetic read head 211 is a magnetoresistive (MR) read head that includes an MR sensing element 204 located between MR shields S1 and S2. In other embodiments, the magnetic read head 211 is a magnetic tunnel junction (MTJ) read head that includes a MTJ sensing device 204 located between MR shields S1 and S2. The magnetic fields of the adjacent magnetized regions in the magnetic disk 112 are detectable by the MR (or MTJ) sensing element 204 as the recorded bits. The SOT device of various embodiments can be incorporated into the read head 211 as the sensing element. An example of an SOT read head is described in co-pending patent application titled “Topological Insulator Based Spin Torque Oscillator Reader,” U.S. application Ser. No. 17/828,226, filed May 31, 2022, assigned to the same assignee of this application, which is herein incorporated by reference.

The write head 210 includes a main pole 220, a leading shield 206, a trailing shield 240, an optional spin orbital torque (SOT) device 250, and a coil 218 that excites the main pole 220. The coil 218 may have a “pancake” structure which winds around a back-contact between the main pole 220 and the trailing shield 240, instead of a “helical” structure shown in FIG. 2. When included, e.g., to achieve a Microwave Assisted Magnetic Recording (MAMR) effect, the SOT device 250 is formed in a gap 254 between the main pole 220 and the trailing shield 240. The main pole 220 includes a trailing taper 242 and a leading taper 244. The trailing taper 242 extends from a location recessed from the MFS 212 to the MFS 212. The leading taper 244 extends from a location recessed from the MFS 212 to the MFS 212. The trailing taper 242 and the leading taper 244 may have the same degree of taper, and the degree of taper is measured with respect to a longitudinal axis 260 of the main pole 220. In some embodiments, the main pole 220 does not include the trailing taper 242 and the leading taper 244. Instead, the main pole 220 includes a trailing side (not shown) and a leading side (not shown), and the trailing side and the leading side are substantially parallel. The main pole 220 may be a magnetic material, such as a FeCo alloy. The leading shield 206 and the trailing shield 240 may be a magnetic material, such as a NiFe alloy. In certain embodiments, the trailing shield 240 can include a trailing shield hot buffer layer 241. The trailing shield hot buffer layer 241 can include a high moment sputter material, such as CoFeN, FeXN, or FeX, where X includes at least one of N, Al, Ni, Co, Ta, Re, Ir, Pt, Rh, Ta, Zr, and Ti. In certain embodiments, the trailing shield 240 does not include a trailing shield hot buffer layer.

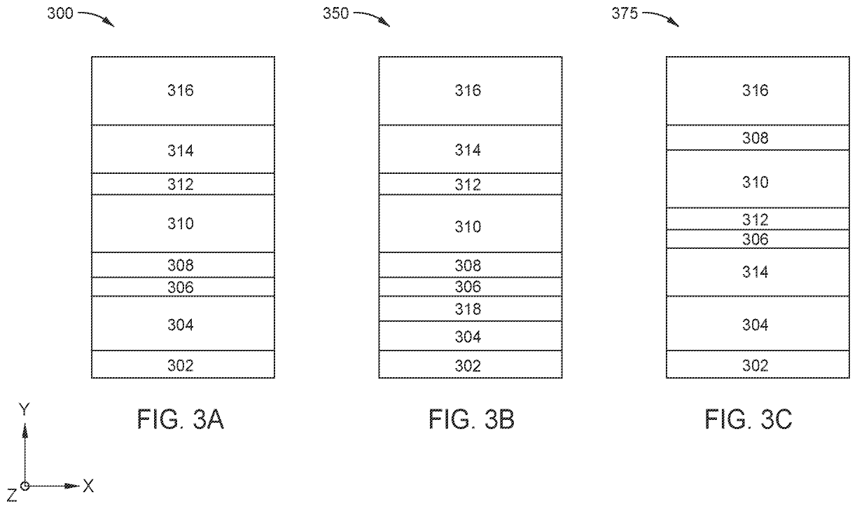

FIG. 3A illustrates a bottom spin orbit torque (SOT) device 300, according to one embodiment. The bottom SOT device 300 comprises an amorphous seed layer 302, which may be disposed over a first shield or substrate (depending on end application, not shown) and/or an insulation layer (not shown), a texture seed layer 304 disposed on the seed layer 302, an insulating layer 306 disposed on the texture seed layer 304, a diffusion barrier layer 308 disposed on the insulating layer 306, a spin Hall effect (SHE) layer or BiSb layer 310 (which may also be referred to herein as a topological insulator (TI) layer 310) disposed on the diffusion barrier layer 308, an interlayer 312 disposed on the BiSb layer 310, a ferromagnetic (FM) layer 314 disposed on the interlayer 312, and a cap layer 316 disposed on the FM layer 314.

FIG. 3B illustrates a bottom SOT device 350, according to another embodiment. The bottom SOT device 350 is similar to the bottom SOT device 300 of FIG. 3A; however, the bottom SOT device 350 comprises a second diffusion barrier layer 318 disposed between the texture seed layer 304 and the insulating layer 306.

FIG. 3C illustrates a top SOT device 375, according to another embodiment. The top SOT device 350 comprises the seed layer 302, the texture seed layer 304 disposed on the seed layer 302, the FM layer 314 disposed on the texture seed layer 304, the insulating layer 306 disposed on the FM layer 314, the interlayer 312 disposed on the insulating layer 306, the BiSb layer 310 disposed on the interlayer 312, the diffusion barrier layer 308 disposed on the BiSb layer 310, and the cap layer 316 disposed on the diffusion barrier layer 308.

The seed layer 302 comprises an amorphous material, such as NiFeTa, NiFeGe, CoFeB, or CoFeBTa, and has a thickness in the y-direction of about 5 Å to about 50 Å. The texture seed layer 304 comprises RuAl, and has a (001) orientation. The texture seed layer 304 provides a (001) orientation or texture to body-centered cubic (BCC) materials or structures and a (012) orientation to the BiSb layer 310. The texture seed layer 304 has a thickness in the y-direction of about 10 Å to about 50 Å. The insulating layer 306 comprises MgO, MgAlO or other Spinel material, and inherits the (001) orientation from the texture seed layer 304. The insulating layer 306 has a thickness in the y-direction of about 3 Å to about 20 Å.

The diffusion barrier layers 308, 318 each individually comprises NiAl and/or RuAl, and inherits the BCC (001) orientation from the texture seed layer 304. The diffusion barrier layers 308, 318 may each individually have a thickness in the y-direction of about 2 Å to about 20 Å. The BiSb layer 310 comprises BiSb, which may be doped or undoped, and has a (012) orientation. The BiSb layer 310 has a thickness in the y-direction of about 30 Å to about 200 Å. In some embodiments, the BiSb layer 310 may be substituted by other topological insulator (TI) materials and may be referred to as an SOT layer or TI layer 310. The interlayer 312 comprises NiAl and/or RuAl, and has a BCC (001) orientation. In some embodiments, the interlayer 312 comprises only NiAl. The interlayer 312 has a thickness in the y-direction of about 2 Å to about 20 Å. NiAl has been found to provide a particularly effective diffusion layer, with Ni and Al being effective at reducing Sb migration without the side effect of also interacting the BiSb in the SOT layer, which reduces device performance.

The FM layer 314 comprises CoFe or NiFe, and inherits the (001) orientation from either the (001) texture seed layer 304 or the (001) interlayer 312, depending on the bottom SOT device 300 or 350, or the top SOT device 375. The FM layer 314 having a (001) texture results in the FM layer 314 being a less magnetic dead layer, having low coercivity, and a shaper interface The FM layer 314 has a thickness in the y-direction of about 3 Å to about 100 Å. The cap layer 316 comprises NiAl, RuAl, Ru, and/or Ta, and has a thickness in the y-direction of about 10 Å to about 50 Å.

The diffusion barrier layers 308, 318 and the interlayer 312 all prevent Sb migration from the BiSb layer 310 into the FM layer 314, or other surrounding layers. The diffusion barrier layers 308, 318 and the interlayer 312 all further providing a strong (001) texture to the FM layer 314, and a strong (012) texture to the BiSb layer 310.

Thus, by including the (001) textured diffusion barrier layer(s) 308, 318 and the (001) interlayer 312, Sb migration from the BiSb layer 310 is reduced, and enables the FM layer 314 to inherit the (001) texture, as the NiAl and/or RuAl of the (001) textured diffusion barrier layer(s) 308, 318 and the (001) interlayer 312 have strong texture transmission properties.

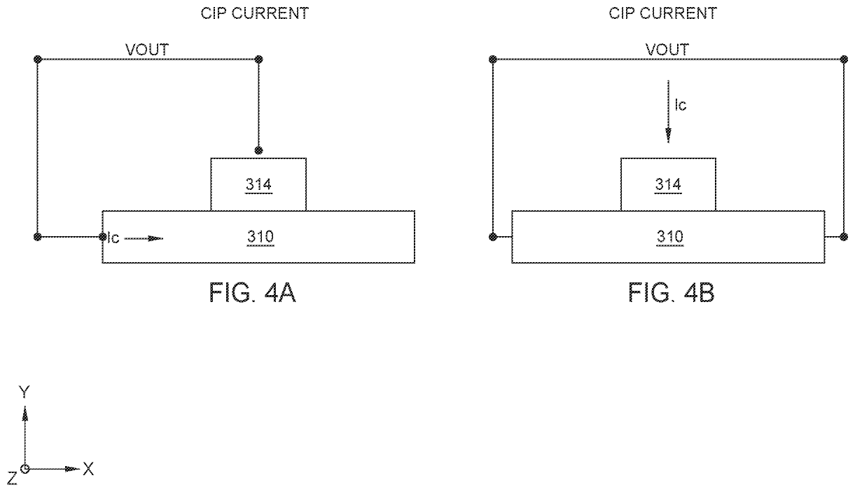

FIG. 4A illustrates a current-in-plane (CIP) SOT device 400, according to one embodiment. The CIP SOT device 400 may be used in combination with the SOT device 300 of FIG. 3A, the SOT device 350 of FIG. 3B, and/or the SOT device 375 of FIG. 3C. The SOT device 400 comprises a TI layer 310 and the FM layer 314 disposed over the TI layer 310. While the FM layer 314 is disposed over the TI layer 310, the TI layer 310 may be disposed over the FM layer 314 instead. The SOT device 400 may comprise additional layers not shown, such as the seed layer 302, the texture seed layer 304, the diffusion barrier layers 308, 318, the interlayer 312, and/or the cap layer 316, as discussed above in FIGS. 3A-3C.

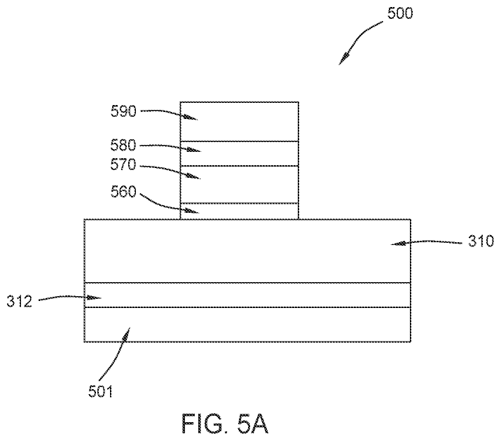

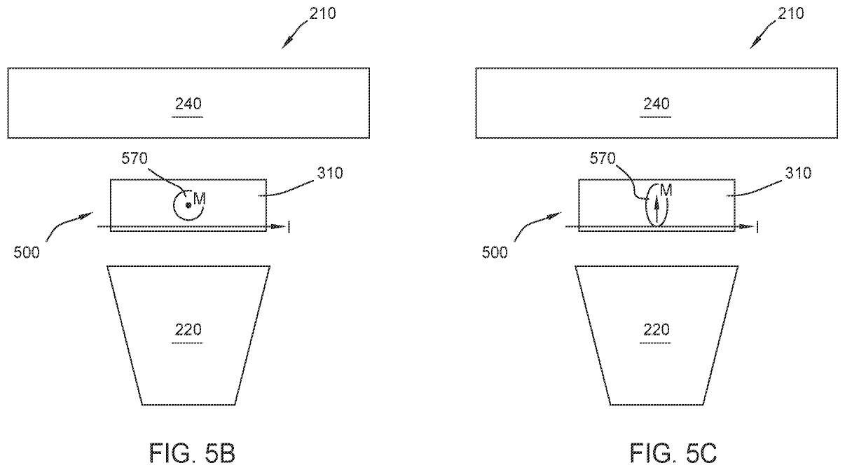

During operation, current (Ic) is applied to the TI layer 310 in the x-direction, or in-plane with the TI layer 310. Due to the spin Hall effect, a spin current is generated and flows perpendicularly into the FM layer 314, causing the FM layer 314 to rotate or switch, which can be detected by measuring the voltage read out (Vout) based on an anomalous Hall effect or tunnel magnetoresistance (TMR) with an optional tunnel barrier layer (not shown) and a top pinned FM layer(s) (not shown). Such CIP SOT devices 400 have fast magnetic switching of the FM layer 314, and generally require the bulk conductivity property of the TI layer 310 to be high for less power consumption during operation. For example, the CIP SOT device 400 may be used in memory applications, such as SOT MRAM, HDD write heads, such as the write head 210 of FIG. 2, magnetic sensors, and SOT-based logic devices, including artificial intelligence (AI) chips. Example write heads and MRAM applications are further shown in FIGS. 5A-C and 6 below.

FIG. 4B illustrates a current-perpendicular-plane (CPP) SOT device 450, according to another embodiment. The CPP SOT device 450 may be used in combination with the SOT device 300 of FIG. 3A, the SOT device 350 of FIG. 3B, and/or the SOT device 375 of FIG. 3C. The SOT device 450 comprises a TI layer 310 and the FM layer 314 disposed over the TI layer 310. While the FM layer 314 is disposed over the TI layer 310, the TI layer 310 may be disposed over the FM layer 314 instead. The SOT device 450 may comprise additional layers not shown, such as the seed layer 302, the texture seed layer 304, the diffusion barrier layers 308, 318, the interlayer 312, and/or the cap layer 316, as discussed above in FIGS. 3A-3C.

During operation, current (Ic) is applied to the top of the FM layer 314 in the −y-direction, or perpendicular to the plane of the TI layer 310. The output voltage (Vout) is read in-plane of the TI layer 310 based on the inverse spin Hall effect (iSHE). Such CPP SOT devices 450 generally require the bulk conductivity property of the TI layer 310 to be lower and more insulating to minimize shunting during signal read out. For example, the CPP SOT device 450 may be used in read heads, such as the read head 211 of FIG. 2 or other magnetic sensor applications. An example SOT read head embodiment is disclosed in co-owned U.S. Pat. No. 11,094,338, titled “SOT Film Stack For Differential Reader,” issued Aug. 17, 2021, and is hereby incorporated by reference.

FIG. 5A is a schematic cross-sectional view of a SOT device 500 for use in a MAMR write head, such as the MAMR write head of the drive 100 of FIG. 1 or other suitable magnetic media drives. The SOT device 500 comprises a BiSb layer 310 with a (012) orientation formed over a interlayer 312 formed over a substrate 501, such as the BiSb layer 310 and the interlayer 312 of FIGS. 3A-4B. A spin torque layer (STL) 570 is formed over the BiSb layer 310. The STL 570 comprises a ferromagnetic material such as one or more layers of CoFe, CoIr, NiFe, and CoFeX alloy wherein X=B, Ta, Re, or Ir.

In certain embodiments, an electrical current shunt block layer 560 is disposed between the BiSb layer 310 and the STL 570. The electrical current shunt blocking layer 560 reduces electrical current from flowing from the BiSb layer 310 to the STL 570 but allows spin orbital coupling of the BiSb layer 310 and the STL 570. In certain embodiments, the electrical current shunt blocking layer 560 comprises a magnetic material which provides greater spin orbital coupling between the BiSb layer 310 and the STL 570 than a non-magnetic material. In certain embodiments, the electrical current shunt blocking layer 560 comprises a magnetic material of FeCo, FeCoM, FeCoMO, FeCoMMeO, FeCoM/MeO stack, FeCoMNiMnMgZnFeO, FeCoM/NiMnMgZnFeO stack, multiple layers/stacks thereof, or combinations thereof in which M is one or more of B, Si, P, Al, Hf, Zr, Nb, Ti, Ta, Mo, Mg, Y, Cu, Cr, and Ni, and Me is Si, Al, Hf, Zr, Nb, Ti, Ta, Mg, Y, or Cr. In certain embodiments, the electrical current shunt blocking layer 560 is formed to a thickness from about 10 Å to about 100 Å. In certain aspects, an electrical current shunt blocking layer 560 having a thickness of over 100 Å may reduce spin orbital coupling of the BiSb layer 310 and the STL 570. In certain aspects, an electrical current shunt blocking layer having a thickness of less than 10 Å may not sufficiently reduce electrical current from BiSb layer 310 to the STL 570.

In certain embodiments, additional layers are formed over the STL 570 such as a spacer layer 580 and a pinning layer 590. The pinning layer 590 can partially pin the STL 570. The pinning layer 590 comprises a single or multiple layers of PtMn, NiMn, IrMn, IrMnCr, CrMnPt, FeMn, other antiferromagnetic materials, or combinations thereof. The spacer layer 580 comprises single or multiple layers of magnesium oxide, aluminum oxide, other non-magnetic materials, or combinations thereof.

FIGS. 5B-5C are schematic MFS views of certain embodiments of a portion of a MAMR write head 210 with a SOT device 500 of FIG. 5A. The MAMR write head 210 can be the write head FIG. 2 or other suitable write heads in the drive 100 of FIG. 1 or other suitable magnetic media drives such as tape drives. The MAMR write head 210 includes a main pole 220 and a trailing shield 240 in a track direction. The SOT device 500 is disposed in a gap between the main pole and the trailing shield 240.

During operation, charge current through a BiSb layer or layer stack 310 acting as a spin Hall layer generates a spin current in the BiSb layer. The spin orbital coupling of the BiSb layer and a spin torque layer (STL) 570 causes switching or precession of magnetization of the STL 570 by the spin orbital coupling of the spin current from the BiSb layer 310. Switching or precession of the magnetization of the STL 570 can generate an assisting AC field to the write field. Energy assisted write heads based on SOT have multiple times greater power efficiency in comparison to MAMR write heads based on spin transfer torque. As shown in FIG. 5B, an easy axis of a magnetization direction of the STL 570 is perpendicular to the MFS from shape anisotropy of the STL 570, from the pinning layer 590 of FIG. 5A, and/or from hard bias elements proximate the STL 570. As shown in FIG. 5C, an easy axis of a magnetization direction of the STL 570 is parallel to the MFS from shape anisotropy of the STL 570, from the pinning layer 590 of FIG. 5A, and/or from hard bias elements proximate the STL 570.

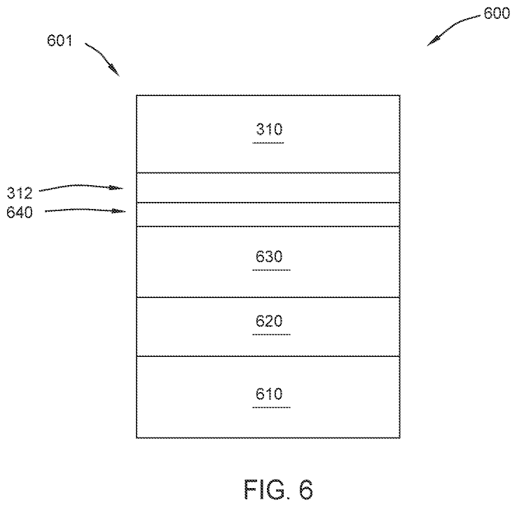

FIG. 6 is a schematic cross-sectional view of a SOT MTJ 601 used as a MRAM device 600. The MRAM device 600 comprises a reference layer (RL) 610, a spacer layer 620 over the RL 610, a recording layer 630 over the spacer layer 620, an interlayer 312 over an electrical current shunt block layer 640 over the recording layer 630, and a BiSb layer or layer stack 310 over the interlayer 312. The BiSb layer 310 and the interlayer 312 may be the BiSb layer 310 and the interlayer 312 of FIGS. 3A-4B.

The RL 610 comprises single or multiple layers of CoFe, other ferromagnetic materials, and combinations thereof. The spacer layer 620 comprises single or multiple layers of magnesium oxide, aluminum oxide, other dielectric materials, or combinations thereof. The recording layer 630 comprises single or multiple layers of CoFe, NiFe, other ferromagnetic materials, or combinations thereof.

As noted above, in certain embodiments, the electrical current shunt block layer 640 is disposed between the interlayer 312 and the recording layer 630. The electrical current shunt blocking layer 640 reduces electrical current from flowing from the BiSb layer 310 to the recording layer 630 but allows spin orbital coupling of the BiSb layer 310 and the recording layer 630. For example, writing to the MRAM device can be enabled by the spin orbital coupling of the BiSb layer and the recording layer 630, which enables switching of magnetization of the recording layer 630 by the spin orbital coupling of the spin current from the BiSb layer 310. In certain embodiments, the electrical current shunt blocking layer 640 comprises a magnetic material which provides greater spin orbital coupling between the BiSb layer 310 and the recording layer 630 than a non-magnetic material. In certain embodiments, the electrical current shunt blocking layer 640 comprises a magnetic material of FeCoM, FeCoMO, FeCoMMeO, FeCoM/MeO stack, FeCoMNiMnMgZnFeO, FeCoM/NiMnMgZnFeO stack, multiple layers/stacks thereof, or combinations thereof, in which M is one or more of B, Si, P, Al, Hf, Zr, Nb, Ti, Ta, Mo, Mg, Y, Cu, Cr, and Ni, and Me is Si, Al, Hf, Zr, Nb, Ti, Ta, Mg, Y, or Cr.

The MRAM device 600 of FIG. 6 may include other layers, such as pinning layers, pinning structures (e.g., a synthetic antiferromagnetic (SAF) pinned structure), electrodes, gates, and other structures. Other MRAM devices besides the structure of FIG. 6 can be formed utilizing a BiSb layer 310 with a (012) orientation over an interlayer 312 to form a SOT MTJ 601.

Therefore, by including the (001) textured diffusion barrier layer(s) and the (001) interlayer in an SOT device, Sb migration from a BiSb layer is reduced, and enables the FM layer to inherit the (001) texture, as the NiAl and/or RuAl of the (001) textured diffusion barrier layer(s) and the (001) interlayer have strong texture transmission properties.

In one embodiment, a spin orbit torque (SOT) device comprises a textured seed layer having a (001) orientation, an insulating layer disposed on the textured seed layer, a diffusion barrier layer having a (001) orientation disposed on the insulating layer, the diffusion barrier layer comprising one or more of NiAl and RuAl, a BiSb layer disposed on the diffusion barrier layer, the BiSb layer having a (012) orientation, an interlayer having a (001) orientation disposed on the BiSb layer, the interlayer comprising one or more of NiAl and RuAl, and a ferromagnetic (FM) layer disposed on the interlayer, the FM layer having a (001) orientation.

The diffusion barrier layer comprises NiAl. The interlayer comprises NiAl. The SOT device further comprises an amorphous seed layer disposed in contact with the textured seed layer. The FM layer comprises CoFe or NiFe. The diffusion barrier layer has a thickness of about 2 Å to about 20 Å, and wherein the interlayer has a thickness of about 2 Å to about 20 Å. A magnetic recording head comprises the SOT device. A magnetic recording device comprises the magnetic recording head. A magneto-resistive memory comprises the SOT device.

In another embodiment, a spin orbit torque (SOT) device comprises an amorphous seed layer, a textured seed layer having a (001) orientation disposed on the amorphous seed layer, an insulating layer disposed over the textured seed layer, a first diffusion barrier layer having a body-centered cubic (BCC) (001) orientation disposed on the insulating layer, the first diffusion barrier layer comprising one or more of NiAl and RuAl, a BiSb layer disposed on the first diffusion barrier layer, the BiSb layer having a (012) orientation, an interlayer having a BCC (001) orientation disposed on the BiSb layer, the interlayer comprising one or more of NiAl and RuAl, and a ferromagnetic (FM) layer disposed on the interlayer, the FM layer having a (001) orientation.

The SOT device further comprises a second diffusion barrier layer disposed between the textured seed layer and the insulating layer, and a cap layer disposed on the FM layer. The second diffusion barrier layer has a BCC (001) orientation and comprises one or more of NiAl and RuAl. The textured seed layer comprises one or more of NiAl and RuAl, and wherein the amorphous seed layer comprises NiFeTa. The first diffusion barrier layer has a thickness of about 2 Å to about 20 Å, wherein the interlayer has a thickness of about 2 Å to about 20 Å, and wherein the FM layer has a thickness of about 3 Å to about 100 Å. A magnetic recording head comprises the SOT device. A magnetic recording device comprises the magnetic recording head. A magneto-resistive memory comprises the SOT device.

In yet another embodiment, a spin orbit torque (SOT) device comprises an amorphous seed layer, a textured seed layer having a (001) orientation disposed in contact with the amorphous seed layer, the textured seed layer comprising one or more of NiAl and RuAl; an insulating layer disposed in contact with the textured seed layer, a diffusion barrier layer having a body-centered cubic (BCC) (001) orientation disposed in contact with the insulating layer, the diffusion barrier layer comprising NiAl, a BiSb layer disposed in contact with the diffusion barrier layer, the BiSb layer having a (012) orientation, an interlayer having a BCC (001) orientation disposed in contact with the BiSb layer, the interlayer comprising NiAl, and a ferromagnetic (FM) layer disposed in contact with the interlayer, the FM layer comprising NiFe or CoFe and having a (001) orientation.

The textured seed layer comprises RuAl. The diffusion barrier layer has a thickness of about 2 Å to about 20 Å, wherein the interlayer has a thickness of about 2 Å to about 20 Å, wherein the FM layer has a thickness of about 3 Å to about 100 Å, and wherein the BiSb layer has a thickness of about 30 Å to about 200 Å. The SOT device further comprises a cap layer disposed in contact with the FM layer. The SOT device is a current-in-plane SOT device. The SOT device is a current-perpendicular-to-plane device. A magnetic recording head comprises the SOT device. A magnetic recording device comprises the magnetic recording head. A magneto-resistive memory comprises the SOT device.

While the foregoing is directed to embodiments of the present disclosure, other and further embodiments of the disclosure may be devised without departing from the basic scope thereof, and the scope thereof is determined by the claims that follow.

1. A spin orbit torque (SOT) device, comprising:
a seed layer comprising NiFeGe or CoFeBTa;
a textured seed layer having a (001) orientation disposed on the seed layer;
an insulating layer having a (001) orientation disposed on the textured seed layer, the insulating layer comprising MgO or MgAlO;
a diffusion barrier layer having a (001) orientation disposed on the insulating layer, the diffusion barrier layer comprising one or more of NiAl and RuAl;
a BiSb layer disposed on the diffusion barrier layer, the BiSb layer having a (012) orientation;
an interlayer having a (001) orientation disposed on the BiSb layer, the interlayer comprising one or more of NiAl and RuAl;
a ferromagnetic (FM) layer disposed on the interlayer, the FM layer having a (001) orientation; and
a cap layer disposed over the FM layer, the cap layer comprising a material selected from the group consisting of: NiAl, RuAl, Ru, Ta, and combinations thereof.

2. The SOT device of claim 1, wherein the diffusion barrier layer comprises NiAl.

3. The SOT device of claim 1, wherein the interlayer comprises NiAl.

4. The SOT device of claim 1, further comprising an amorphous seed layer disposed in contact with the textured seed layer.

5. The SOT device of claim 1, wherein the FM layer comprises CoFe or NiFe.

6. The SOT device of claim 1, wherein the diffusion barrier layer has a thickness of about 2 Å to about 20 Å, and wherein the interlayer has a thickness of about 2 Å to about 20 Å.

7. A magnetic recording head comprising the SOT device of claim 1.

8. A magnetic recording device comprising the magnetic recording head of claim 7.

9. A magneto-resistive memory comprising the SOT device of claim 1.

10. A spin orbit torque (SOT) device, comprising:
an amorphous seed layer comprising NiFeGe or CoFeBTa;
a textured seed layer having a (001) orientation disposed on the amorphous seed layer;
an insulating layer having a (001) orientation disposed over the textured seed layer, the insulating layer comprising MgO or MgAlO;
a first diffusion barrier layer having a body-centered cubic (BCC) (001) orientation disposed on the insulating layer, the first diffusion barrier layer comprising one or more of NiAl and RuAl;
a BiSb layer disposed on the first diffusion barrier layer, the BiSb layer having a (012) orientation;
an interlayer having a BCC (001) orientation disposed on the BiSb layer, the interlayer comprising one or more of NiAl and RuAl;
a ferromagnetic (FM) layer disposed on the interlayer, the FM layer having a (001) orientation; and
a cap layer disposed over the FM layer, the cap layer comprising a material selected from the group consisting of: NiAl, RuAl, Ru, Ta, and combinations thereof.

11. The SOT device of claim 10, further comprising:
a second diffusion barrier layer disposed between the textured seed layer and the insulating layer; and
a cap layer disposed on the FM layer.

12. The SOT device of claim 11, wherein the second diffusion barrier layer has a BCC (001) orientation and comprises one or more of NiAl and RuAl.

13. The SOT device of claim 10, wherein the textured seed layer comprises one or more of NiAl and RuAl, and wherein the amorphous seed layer comprises NiFeTa.

14. The SOT device of claim 10, wherein the first diffusion barrier layer has a thickness of about 2 Å to about 20 Å, wherein the interlayer has a thickness of about 2 Å to about 20 Å, and wherein the FM layer has a thickness of about 3 Å to about 100 Å.

15. A magnetic recording head comprising the SOT device of claim 10.

16. A magnetic recording device comprising the magnetic recording head of claim 15.

17. A magneto-resistive memory comprising the SOT device of claim 10.

18. A spin orbit torque (SOT) device, comprising:
an amorphous seed layer comprising NiFeGe or CoFeBTa;
a textured seed layer having a (001) orientation disposed in contact with the amorphous seed layer, the textured seed layer comprising one or more of NiAl and RuAl;
an insulating layer having a (001) orientation disposed in contact with the textured seed layer, the insulating layer comprising MgO or MgAlO;
a diffusion barrier layer having a body-centered cubic (BCC) (001) orientation disposed in contact with the insulating layer, the diffusion barrier layer comprising NiAl;
a BiSb layer disposed in contact with the diffusion barrier layer, the BiSb layer having a (012) orientation;
an interlayer having a BCC (001) orientation disposed in contact with the BiSb layer, the interlayer comprising NiAl;
a ferromagnetic (FM) layer disposed in contact with the interlayer, the FM layer comprising NiFe or CoFe and having a (001) orientation; and
a cap layer disposed over the FM layer, the cap layer comprising a material selected from the group consisting of: NiAl, RuAl, Ru, Ta, and combinations thereof.

19. The SOT device of claim 18, wherein the textured seed layer comprises RuAl.

20. The SOT device of claim 18, wherein the diffusion barrier layer has a thickness of about 2 Å to about 20 Å, wherein the interlayer has a thickness of about 2 Å to about 20 Å, wherein the FM layer has a thickness of about 3 Å to about 100 Å, and wherein the BiSb layer has a thickness of about 30 Å to about 200 Å.

21. The SOT device of claim 18, further comprising a cap layer disposed in contact with the FM layer.

22. The SOT device of claim 18, wherein the SOT device is a current-in-plane SOT device.

23. The SOT device of claim 18, wherein the SOT device is a current-perpendicular-to-plane device.

24. A magnetic recording head comprising the SOT device of claim 18.

25. A magnetic recording device comprising the magnetic recording head of claim 24.

26. A magneto-resistive memory comprising the SOT device of claim 18.
